(19) United States
(12) Patent Application Publication
(10) Pub. No.: US 2007/0190680 A1
(43) Pub. Date: Aug. 16, 2007

(54) MEMS device and manufacturing process thereof

(75) Inventors: Hiroshi Fukuda, London (GB); Jeong Hee Won, Tokyo (JP)

Correspondence Address: Stanley P. Fisher;Reed Smith LLP, Suite 1400, 3110 Fairview Park Drive, Falls Church, VA, 22042-4503, US

(73) Assignee: Hitachi, Ltd.

(21) Appl. No.: 11/650,430

(22) Filed: Jan. 8, 2007

(30) Foreign Application Priority Data
Feb. 13, 2006 (JP) 2006-035197

(51) Int. Cl. H01L 21/00

(52) U.S. Cl. 438/50

(57) ABSTRACT

MEMS devices require special cavity formation and sealing steps such as wafer bonding which reduce the yield and increase the cost. In addition, it is difficult to form a cavity of a large area by the LSI process owing to a residual stress of a sealing film which will be a lid. This leads to a difficulty of realizing an integrated MEMS having a MEMS and a high-performance LSI mounted on one substrate. The lid (or diaphragm) covering therewith a cavity is equipped with slits or beams. During the formation of the cavity, the slits are deformed to absorb and relax the internal stress of the thin sealing film. Then, the cavity is sealed by filling the open portions of the film overlying the cavity between the inside and outside of the cavity. The cavity is formed by removing a portion of the interlayer film of LSI multilevel interconnects and the lid is made of a LSI-process thin film.

### CLAIM PRIORITY

The present application claims priority from Japanese application JP 2006-035197 filed on Feb. 13, 2006, the content of which is hereby incorporated by reference into this application.

### FIELD OF THE INVENTION

The present invention relates to a microelectromechanical systems (MEMS) device and manufacturing process thereof. In particular, the invention pertains to a technology effective when applied to a device having a semiconductor integrated circuit and MEMS integrated therein, a processing technology, and a sensor or switch utilizing the MEMS device.

### BACKGROUND OF THE INVENTION

Microfabrication technology which has realized high-performance and high-integration semiconductor integrated circuits is now being utilized for the development of microelectromechanical systems (MEMS) technology for forming mechanical sensors, such as pressure sensors and accelerometers, and minute mechanical parts, such as microswitches and oscillators, and micromechanical systems. MEMS may be classified into bulk MEMS obtained by processing of a Si substrate itself, and surface MEMS formed by repeating deposition and patterning of thin films on the surface of a Si substrate. In the application of MEMS to a sensor, mechanical deformation of a structure by an external force or the like is converted into electric signals as a piezo resistance change or capacitance change, and is then outputted. The output is usually signal-processed by a semiconductor integrated circuit (LSI). In the application of MEMS to an oscillator, the input/output of the oscillator is connected to a high frequency circuit.

MEMS are often used in combination with LSI. When MEMS is used in combination with signal processing LSI, miniaturization of the system becomes difficult because they are formed as separate chips. MEMS and LSI are usually formed on respective Si substrates so that monolithic integration on one substrate is a natural consequence. It has already been employed in some products.

MEMS typically include a movable portion so that they need some adjacent free space. When the movable portion is a structure such as an acceleration sensor, oscillator or switch, it needs a cover (lid) for protecting the movable portion from the outside world during use. When the movable portion is a pressure sensor, ultrasonic transducer, MEMS microphone or the like, on the other hand, a cavity is brought into contact with the outside world via a diaphragm (U.S. Pat. No. 5,596,219). The above-described free space (which will hereinafter be called “cavity”) having a cover thereon (having a movable portion protected therewith) is often required to have sufficient airtightness to prevent deterioration of materials constituting the structure and avoid invasion of water or the like from the outside word. When the movable portion oscillates, the pressure in the cavity must be maintained low to attain oscillation of a high Q factor. Sealing and packaging for this purpose are usually realized by lamination (bonding) with another substrate.

As such, a device having MEMS and LSI integrated and sealed therein may be formed, and some examples are described below. For example, an acceleration sensor or vibration gyroscope using a mass made of a polysilicon (poly Si) film having a thickness of from about 2 μm to 4 μm is, after capacitance voltage conversion, integrated with an analogue circuit such as operational amplifier. The sensor mechanism portion (placed on a Si substrate partially via a cavity) and the analogue circuit portion are placed in different regions (adjacent) on the plane of the substrate. The entirety of the sensor mechanism is sealed with a cover thereover.

A digital mirror device (DMD), which realizes an image device by placing movable metal films having a reflection surface in a matrix form and electro-statically controlling their directions to turn on or off the light, is presently available. This device is sealed at the upper portion thereof with a transparent plate which transmits light.

A technology of forming RF-MEMS (switch, filter) over a LSI by the so-called Cu damascene wiring process has been previously disclosed. In this technology, both a movable portion and a cavity are formed by the damascene process. This report also includes a method of sealing after formation of the movable portion (U.S. Pat. No. 6,635,506B2).

An example of sealing without depending on the bonding technology is described in U.S. Patent Application Laid-Open No. 2004/0183214A1. Also reported, as a zero-level packaging by the so-called thick film process, is a process of forming a cavity by forming a pattern of a thick PSG film or photoresist film so as to cover a structure, depositing thereover a silicon nitride film or metal film as a cover and removing the PSG film or photoresist film via an opening made in a portion of the cover.

Certain of these problems may be solved by aspects of the present invention, at least in that it provides a process of sealing the cavity of a structure, which has been formed by a wiring process of LSI, using those same LSI processes. More specifically, after a movable portion serving as an electrode is formed in an interlayer insulating film by using an interconnect layer in accordance with the multilayer wiring process, and the upper portion of it is covered with a metal layer having minute holes, the interlayer insulating film around the movable portion is removed via the minute holes, followed by a sealing of the minute holes. By controlling the shape of the structure so as to prevent its mechanical properties from depending on the dimension or shape of the cavity, MEMS with high precision can be realized by such a simple process.

Such MEMS and sealing technology thereof are described, for example, in A monthly Publication of The Japan Society of Applied Physics, 73(9), November Issue, 1158-1165(2004) published by the Japan Society of Applied Physics.

It has, on the other hand, been proposed to equip a support in a cavity and place a movable portion so as to avoid the position of the support. According to the proposal, the support is made of a material resistant to etching of a sacrificial layer and it is allowed to serve as a lateral-direction stopper for the sacrificial layer etching. It has also been reported that a support is placed so as to avoid a position of the movable portion and is made of a sealing film.

Moreover, it has been proposed to dispose a support in a lid of the cavity or a sealing film (U.S. Pat. No. 5,760,455). A support made of a sacrificial layer may be disposed in a cavity for an ultrasonic transducer (U.S. Pat. No. 6,262,946B1).

### SUMMARY OF THE INVENTION

A first problem to be overcome is that the conventional MEMS device needs special cavity forming and sealing steps.

Sealing of MEMS by lamination (bonding) with a wafer requires a special step of preparing, namely a lid, a wafer such as glass having trenches or through-holes formed therein, and binding a wafer having MEMS formed thereon with the above-described wafer through anodic bonding or a special adhesive. This complicates the process and may cause problems such as fluctuations or variations in properties, reduction in yield, and cost increase. As another sealing method by lamination, a method of having supports and bringing two wafers into contact at the supports is proposed, but this method is accompanied with the same problems.

A method of sealing using an LSI process, on the other hand, has difficulty in sealing a cavity of a large area owing to a residual stress of a sealing film serving as a lid. More specifically, a sealing film of a large area may be broken or become uneven by the residual stress. Poly Si subjected to stress relaxation at high temperatures is known as a film having a small residual stress, but it needs high heat processing so that it is not suited for MEMS or LSI integrated MEMS including metal interconnects. When the sealing film is made thicker in order to heighten the mechanical strength of the lid, an increase in the influence of the stress cannot be ignored. When the sealing film is made of a film stack, exfoliation may occur at the interface between different materials. Existence of a difference in stress between thin films constituting the film stack may lead to appearance of unevenness in the lid (diaphragm). The sealing film must satisfy, in addition to low stress, various properties such as mechanical strength, moisture resistance, sealing performance and chemical resistance. The low stress and other required properties sometimes cannot be satisfied simultaneously. Materials for the sealing film are therefore limited.

A method of forming the cavity by the damascene process requires a special step of burying a sacrificial layer in an interlayer film.

When the residual stress is a tensile stress, even if the area of the cavity is adjusted to fall within a range not breaking the film, there is a fear of causing a deflection (convex deflection) over the chip. This may hinder the normal operation of the MEMS.

A method of sealing by using the above-described thick film process, on the other hand, requires a step of patterning of a PSG film into a special shape, or a special resist process of a thick film, and also requires a high temperature process for the deposition of SiN, such that it cannot employ Al interconnects for the MEMS.

There is disclosed the step of disposing a support in a cavity and placing a movable portion while avoiding the place of the support in order to heighten the strength of the sealing film. The support also serves as a lateral-direction stopper in the etching of a sacrificial layer, and is made of a material different from that used for the sacrificial layer so that this complicates the process.

When a support made of a sacrificial layer is disposed in the cavity of an ultrasonic transducer, a movable structure cannot exist inside of the cavity.

Thus, the present invention provides microelectromechanical systems equipped with a thin film of a large area for the MEMS structure, or a cavity of a large area (large volume) having high air-tightness for placing the MEMS structure therein, each formable in a convenient manner.

The present invention also provides a manufacturing process of microelectromechanical systems having a thin film of a large area for the MEMS structure or a cavity of a large area (large volume) for disposing the MEMS structure therein by employing a standard manufacturing step of CMOS LSI or a standard wiring step constituting the above-described step.

The present invention can be attained by, in an MEMS having a cavity (and a movable body disposed therein), placing a thin-film “lid” (which herein refers to the cavity-masking layer that is sealed by a sealing by a sealing film), or diaphragm, to cover the upper portion of the cavity, equipping the lid with slits, beams or springs for releasing the internal stress of the thin film, and disposing a sealing film for burying therewith an opening portion for connecting the inside and outside of the cavity in a center region or peripheral region of the lid (or diaphragm). The slits, beams or springs absorb and relax the stress of the thin film by the elastic deformation occurring simultaneously with the formation of the cavity. The slits, beams or springs are formed and disposed preferably to avoid concentration of the stress to a specific site. For example, it is desired to dispose them so as to constitute an unstretchable beam. In the MEMS having a cavity and a movable structure disposed inside of the cavity, the thin film can be used as a lid of the cavity. In the MEMS having a diaphragm and cavity, the thin film can be used as a thin film for diaphragm. The lid or diaphragm means a portion of the thin film over the cavity and it does not necessarily cover the whole upper surface of the cavity.

For example, it is possible to suspend a lid (or diaphragm) on the cavity via the beam or spring fixed partially to the periphery of the cavity and fill the sealing film in the space between the lid (or diaphragm) and periphery of the cavity. The stress of the thin film can be relaxed by the elastic deformation of the beam or spring.

It is also possible to form a first slit in the L shape, T shape or cross shape in the lid (or diaphragm) and a second slit which is disposed in substantially parallel to at least one side of the L-shaped, T-shaped or cross-shaped slit, relax the stress of the thin film by elastic deformation of the beam sandwiched by these two slits, and seal the slits by the sealing film.

The width of the slits is preferably greater than the maximum value of the displacement amount at the relative position of the position coordinate on the slit profile when the stress of the thin-film lid is relaxed by the formation of the cavity. The width of the beam is preferably minimized enough to generate elastic deformation sufficient for stress relaxation.

The slits are preferably placed at the periphery of the lid, but they may be dispersed suitably in the inside region thereof.

When the slits are placed in the center region of the lid, the sealing film for filling therewith the slits can constitute a support of the lid, reaching the bottom portion of the cavity. In this case, it is desired to place the support so as not to disturb the vibration motion of the movable body. The support may be composed of a portion of the sacrificial layer. The sealing film for filling in the slits does not necessarily reach the bottom portion of the cavity. In this case, the width of the slit is preferably smaller than twice as much as the thickness of the sealing film.

The present invention can be attained by disposal of a plurality of columns for supporting the thin film. When the above-described thin film is used as a lid of the cavity including therein a movable structure, the columns are preferably located outside a movable range of the movable structure. The column may contain at least a portion of a sacrificial layer. The column may be composed of the above-described sealing material.

The effect of the slits will next be described schematically based on FIGS. 1 to 3. FIG. 1 illustrates a structure obtained by stacking a sacrificial layer 2 over a substrate 1 and then forming thereover a lid equipped with slits 3 and minute etching holes 4. FIG. 1A is a plain view of the lid 5, while FIG. 1B is a cross-sectional view thereof.

When a cavity 6 is formed by removing the sacrificial layer 2 by etching via the slits 3 and minute etching holes 4, deformation of the slits 3 and beams 7 defined thereby occurs as illustrated in FIG. 2 when a thin film constituting the lid 5 has a tensile stress, while deformation of the slits 3 and beams 7 defined thereby occurs when a thin film has a compressive stress. By the deformation, the residual stress of the lid is reduced and destruction of the film or generation of unevenness of the film can be suppressed.

FIGS. 15 to 17 illustrate the simulation results. The initial residual stress of a film is set at about 3 MPa.

FIG. 15 illustrates simulation results of the residual stress distribution of a film equipped with slits in parallel to sides of the film, respectively, around the cavity. The results have revealed that in spite of a reduction in the residual stress of the film in the cavity region, the stress concentrates on the base of the slits. This occurs because the stress is not released from the base portion of the slit which remains undeformed.

FIG. 16 illustrates simulation results of the residual stress when the slits have an improved shape. The residual stress of the film in the cavity region is reduced and the stress concentration is also suppressed. The location of the slits can be changed variously. In FIG. 16, for example, the tensile stress applied to the beam itself is not released but the stress of the beam itself may be released by making both ends of the beam free.

FIG. 17 illustrates simulation results of the residual stress when the slits are not only located at the periphery of the lid but also dispersed in the inside region. This decreases the deformation amount per slit, thereby suppressing a change in the slit width even if the cavity has a large area. Excessive increase of the slit width leads to difficulty in sealing. Excessive decrease of the slit width, on the other hand, leads to difficulty in further stress relaxation.

The formation method of the cavity is not limited to that illustrated in FIGS. 1 to 3. For example, the cavity may be formed by forming the pattern of a sacrificial layer in a cavity formation region, covering the sacrificial layer with a thin film serving as a lid, forming openings in a portion of the thin film, and removing, by etching, the sacrificial layer covered with the lid via the opening. In this case, formation of slits as illustrated in FIG. 1 over the cavity formation region and release of the residual stress from the thin film serving as the lid have almost similar effects to the above-described ones.

The present invention can be attained by the following manufacturing process. A second thin film is stacked over a first thin film (also serving as a sacrificial layer) and slits, beams or springs and minute holes are formed at predetermined positions of the second thin film over a cavity formation region. Via slits or opening portions around the beams or springs, and minute holes, the first thin film is partially removed and a cavity is formed in the first thin film below the second thin film. A sealing material is then deposited to seal therewith the slits or opening portions around the beams or springs, and minute holes.

When the cavity is formed, the second thin film in the region containing slits, beams or springs becomes deformable freely in this space while being fixed at fixed ends around the cavity. Owing to the residual stress of the film, elastic deformation of the slits, beams or springs occur, leading to the stress relaxation.

The cavity is formed below the existing region of the minute holes so that the shape of the cavity can be determined freely depending on the location of the minute holes. By locating a non-existing region of the minute holes in a portion of the existing region of the minute holes, the first thin film is left as a column in a portion of the cavity. The second thin film over the column is fixed in a horizontal direction so that slits for stress absorption are preferably located around the column. In addition, the column is preferably placed at substantially a symmetry center (fixed point of deformation determined by the removal of the sacrificial layer) of the stress strain of the lid.

When a sealing film is deposited to seal therewith the slits or openings around the beams or springs, and minute holes, formation of a relatively large opening pattern as one of the slits, openings around the beams or springs, or minute holes makes it possible to deposit the sealing film inside of the cavity and allow it to serve as a column for supporting the lid. In this case, the opening pattern is transferred by the residual stress and fixed at this position so that the film is fixed under stress relaxation.

As film materials, insulating films such as SiO₂ and metal or semiconductor thin films such as W, WSi and poly Si can be used for the first thin film and second thin film, respectively. In this case, the sacrificial layer (first thin film) can be etched by wet etching with an aqueous HF solution or vapor phase etching with vapor HF. The minute holes and minute slits can be sealed by a conformal thin film (for example, Si oxide film by thermal CVD) having deposition properties can be used. These material processes are widely used in an LSI step. The present invention is therefore suited for forming a cavity or a diaphragm of a large area (large volume) for installing therein the MEMS structure by using a standard manufacturing process of CMOS LSI or a standard wiring step which is a portion of this manufacturing process. It is also possible to use a metal (semiconductor) film such as poly Si and an insulating film such as SiO₂ as the first thin film and the second thin film, respectively and vapor phase etching with XeF₂ as etching of the sacrificial layer (first thin film). Use of vapor phase etching has an advantage of suppressing adhesion between the lid and substrate, which will otherwise occur by a capillary force. The lid of the invention having slits for stress release is apt to undergo vertical deformation so that it may be influenced by a capillary force. It is therefore preferred to use known supercritical drying process in combination as needed when the vapor phase etching or wet etching is employed.

Described specifically, first, a movable portion serving as an electrode, which is an MEMS structure, is formed in an interlayer insulating film by using the LSI process (multilevel wiring process). After formation of a (metal) thin film layer having minute holes over the movable portion, the interlayer insulating film around the movable portion is removed by etching via the minute holes. In the final step, the minute holes are sealed. The MEMS are located in a cavity formed by removing a portion of the interlayer film of the LSI multilevel interconnects below the thin film layer. As the thin film layer, a material (for example, an upper-level interconnect layer) having a sufficiently small etching rate relative to that of the interlayer insulating film is employed. After the etching, the minute etching holes formed in the thin film are sealed by depositing, over the thin film, a thin film (CVD insulating film, etc.) having relatively isotropic deposition properties. Formation of these thin films and etching for the removal of the interlayer film are performed within the ordinary CMOS process step. The movable structure formed in the cavity is composed of one of an interconnect layer, poly Si on the Si substrate, SiGe layer, and SOI layer, or a desired combination of them.

Such a structure is formed in the cavity and is fixed, by an (elastically) deformable LSI material or metal interconnect, to an interlayer film surrounding therewith the cavity. The MEMS structure is designed so that its mechanical properties are determined by the dimension of the structure itself not depending on the shape of the cavity. Described specifically, the dimensional precision of the cavity has almost no influence on the mechanical properties of the MEMS by disposing (1) a portion fixed to an interlayer film around the cavity and large enough not to substantially undergo elastic deformation, (2) a movable portion, and (3) an elastic deformation portion connecting (1) to (2). The dimensional precision of the structure is defined by the ordinary wiring pattern precision of LSI. This precision is by far higher than the processing precision of the conventional bulk MEMS so that mechanical properties of high precision can be guaranteed.

The MEMS structure is formed using an interconnect layer so that it has, in addition to a mechanical function as a mass, an electrical function as an electrode and interconnect. Actuation and sensing are performed by a static force and capacitance between an electrically independent electrode fixed to the interlayer film and the movable portion. Since the mass has the above-described integrated structure, an acceleration sensor, vibration gyroscope (angular rate sensor), or the like can be realized. The mechanical connection (beam) and electrical connection (interconnect, capacitance for actuation (actuator) and detection, etc.) between the movable portion and a peripheral portion thereof may be performed by separate layers constituting the LSI. Reliability can be improved by sandwiching the movable portion between upper-level layers of multi-level interconnect layers, thereby limiting a mobility range of the movable portion.

The invention is characterized in that any one of a vibration sensor, acceleration sensor, gyroscope sensor, switch and oscillator having the above-described structure is, together with LSI, mounted on a substrate, and that the movable portion is formed using the interconnect (or pad) layer of LSI, or formed over an interconnect layer of LSI (in a two-dimensionally overlapping region).

Each of these MEMS devices can be integrated with LSI. First, a transistor of LSI is formed over a Si substrate. Multi-level interconnect layers are then formed over the transistor and at the same time, a sensor-MEMS structure is formed in an interlayer insulating film between these multilevel interconnect layers over the same substrate, followed by formation and sealing of a cavity. Alternatively, after formation of the sensor-MEMS structure over the Si substrate, LSI is fabricated over the same substrate, followed by formation and sealing of the cavity.

The present invention makes it possible to provide a MEMS device which has a thin film of a large area for MEMS structure or a highly air-tight cavity of a large area for disposing the MEMS structure therein, each available in a convenient manner.

Moreover, the present invention makes it possible to provide a manufacturing process of an MEMS device capable of forming a thin film of a large area for the MEMS structure or a cavity of a large area for disposing the MEMS structure therein by employing a standard manufacturing step of CMOS LSI or a standard wiring step constituting the above-described step.

### BRIEF DESCRIPTION OF THE DRAWINGS

FIGS. 1A and 1B are each a schematic view illustrating the principle of the present invention;

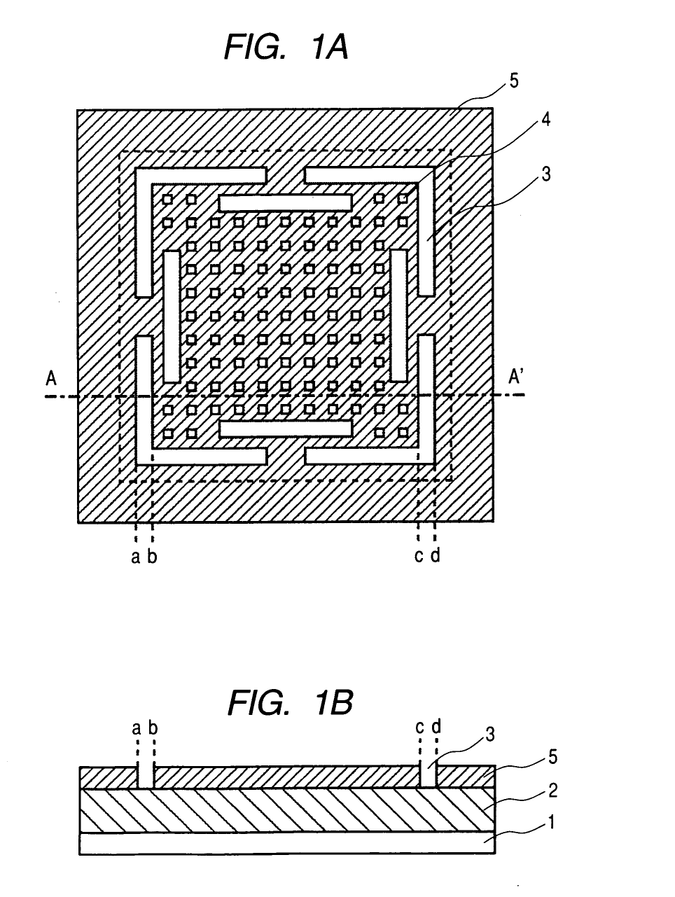

FIGS. 2A and 2B are each a schematic view illustrating the principle of the present invention;

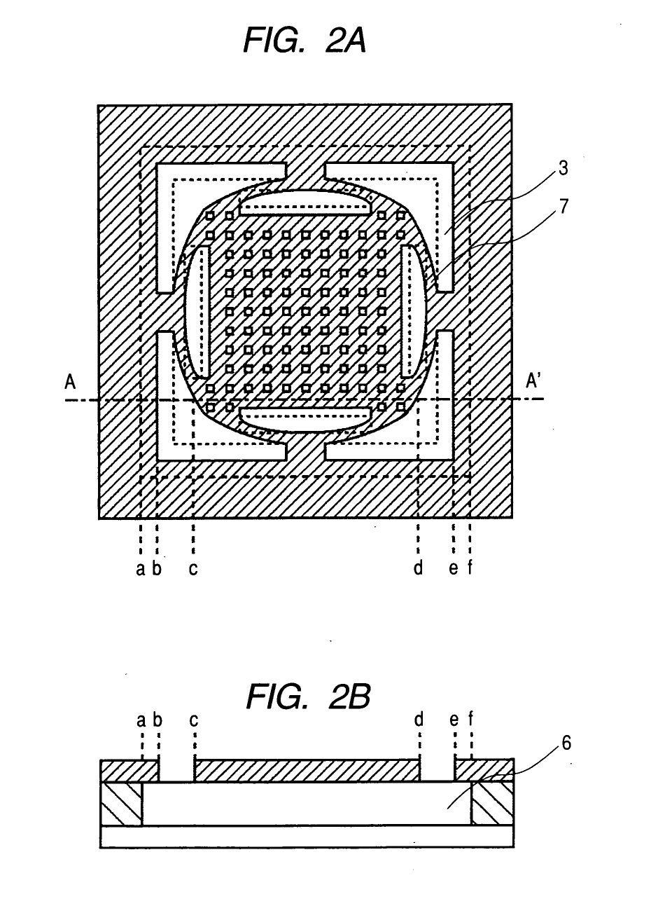

FIGS. 3A and 3B are each a schematic view illustrating the principle of the present invention;

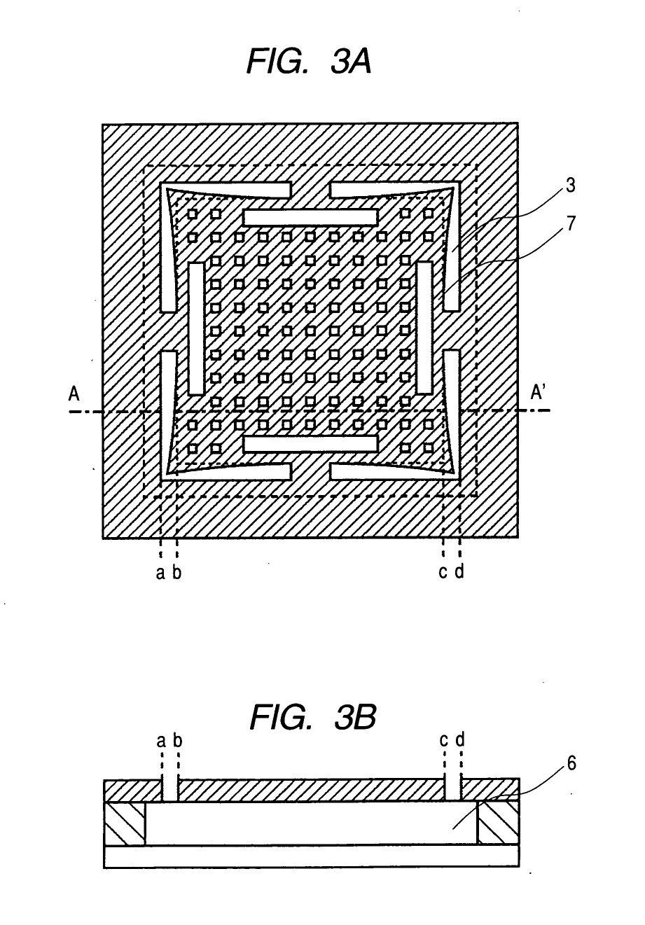

FIGS. 4A, 4B, and 4C are each a schematic cross-sectional view illustrating the manufacturing process of a biaxial acceleration sensor according to the first embodiment of the present invention;

FIGS. 5A, 5B and 5C are each a schematic cross-sectional view illustrating the manufacturing process of the biaxial acceleration sensor according to the first embodiment of the present invention;

FIGS. 6A and 6B are each a schematic view illustrating the plane structure of the main layer of the biaxial acceleration sensor according to the first embodiment of the present invention;

FIG. 7 is a circuit block diagram of a signal detection circuit of the biaxial acceleration sensor according to the first embodiment of the present invention;

FIGS. 8A and 8B are each a schematic view illustrating the modification example of the plane structure of the main layer of the biaxial acceleration sensor according to the first embodiment of the present invention;

FIG. 9 is a schematic view illustrating the plane structure of the main layer of an angular rate sensor (vibration gyroscope) according to a second embodiment of the present invention;

FIG. 10 is a schematic view illustrating the plane structure of the main layer of the angular rate sensor (vibration gyroscope) according to the second embodiment of the present invention;

FIGS. 11A, 11B, 11C, 11D, 11E, 11F are each a schematic cross-sectional view illustrating a manufacturing process of the angular rate sensor (vibration gyroscope) according to the second embodiment of the present invention;

FIG. 12 is a schematic view illustrating the plane structure of the main layer of an ultrasonic transducer according to a third embodiment of the present invention;

FIGS. 13A, 13B and 13C are each a schematic cross-sectional view illustrating the manufacturing process of the ultrasonic transducer according to the third embodiment of the present invention;

FIGS. 14A and 14B are each a schematic cross-sectional view illustrating the manufacturing process of the ultrasonic transducer according to the third embodiment of the present invention;

FIG. 15A is a characteristic diagram illustrating the stress distribution which is a simulation result for exhibiting the effect of the present invention, while FIG. 15B is an auxiliary diagram for explaining the pattern employed for the calculation;

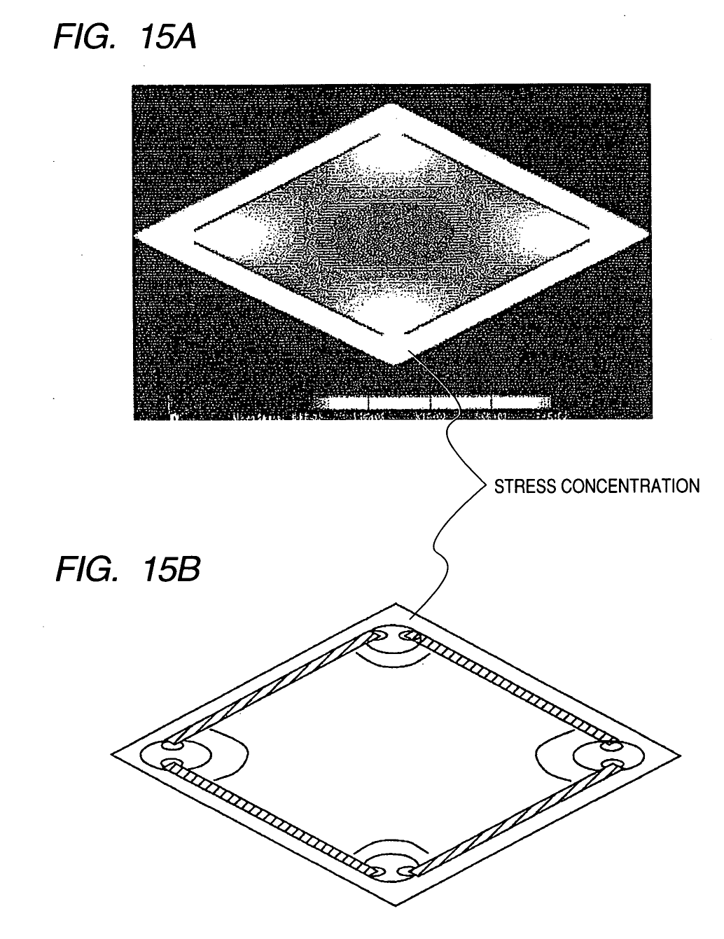

FIG. 16A is a characteristic diagram illustrating the stress distribution which is a simulation result for exhibiting the effect of the present invention, while FIG. 16B is an auxiliary diagram for explaining the pattern employed for the calculation;

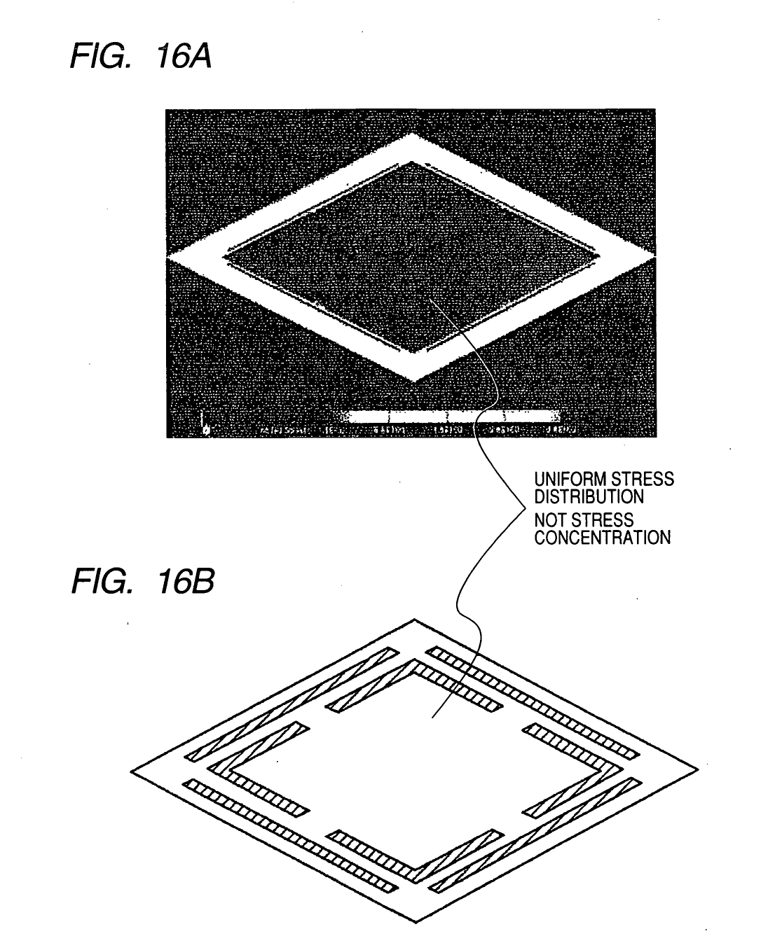

FIG. 17A is a characteristic diagram illustrating the stress distribution which is a simulation result for exhibiting the effect of the present invention, while FIG. 17B is an auxiliary diagram for explaining the pattern employed for the calculation; and

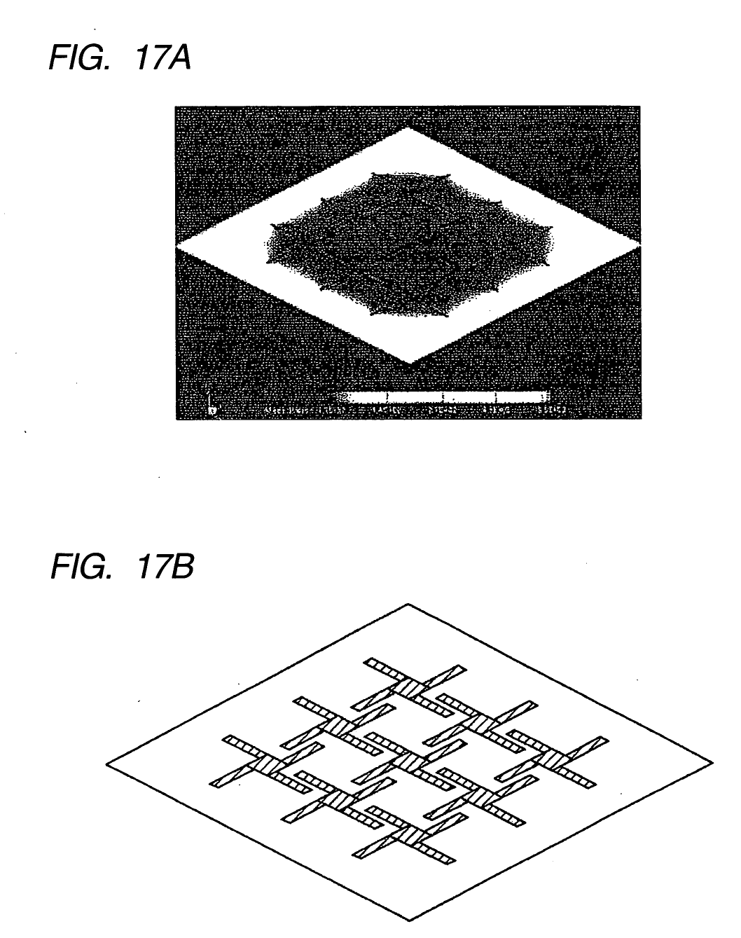

FIG. 18 is a schematic view illustrating another plane structure of the main layer of an angular rate sensor (vibration gyroscope) according to the second embodiment of the present invention.

### DETAILED DESCRIPTION OF THE PREFERRED EMBODIMENTS

Embodiments of the present invention will hereinafter be described specifically based on accompanying drawings.

### First Embodiment

A biaxial acceleration (vibration) sensor according to a first embodiment of the present invention will be described.

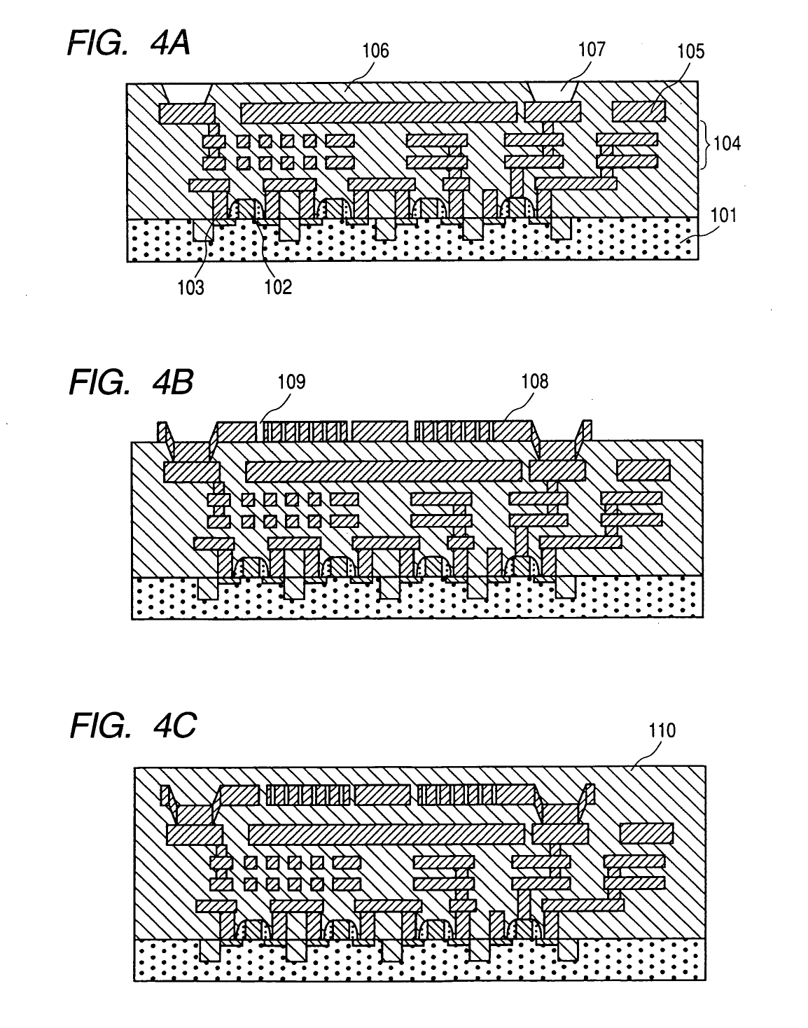

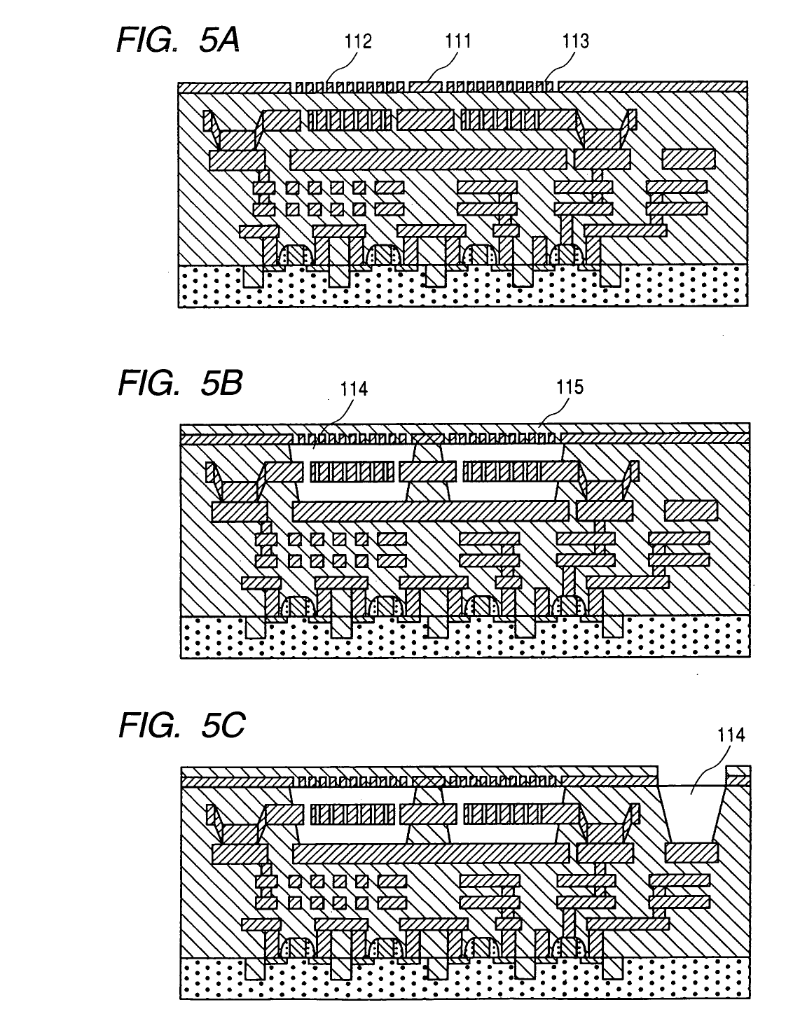

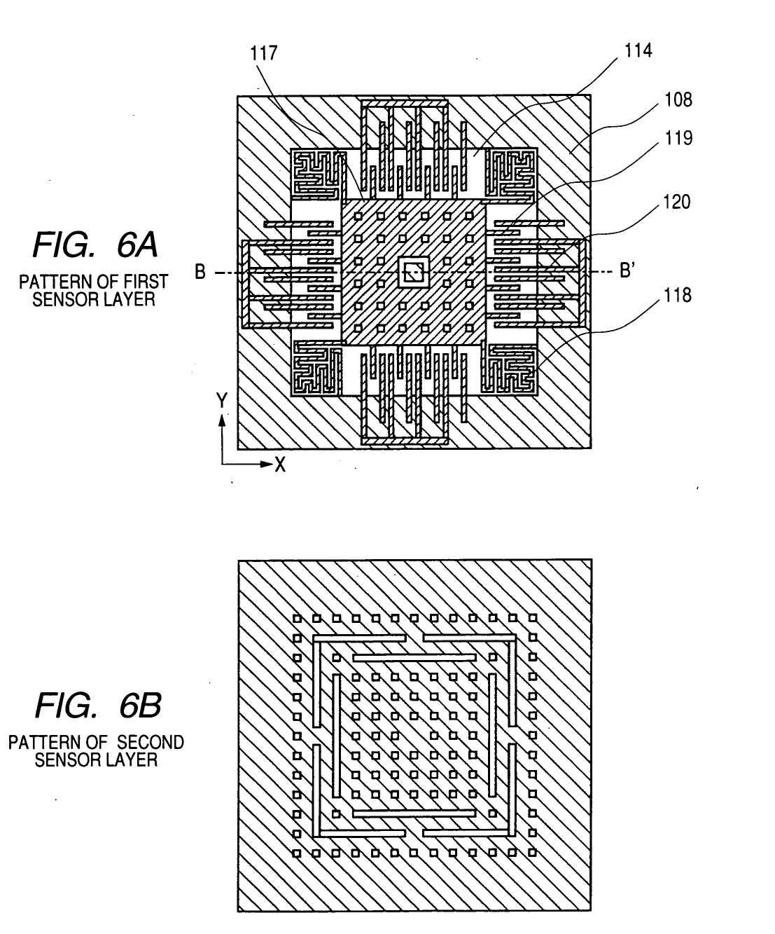

FIGS. 4A, 4B and 4C and FIGS. 5A, 5B and 5C are each a schematic cross-sectional view for explaining the manufacturing process of the sensor according to this embodiment, while FIGS. 6A and 6B are each a schematic view of a plane pattern in each layer of the main process step.

In accordance with the conventional process of a CMOS integrated circuit, a signal-processing integrated circuit transistor 102 for sensor, contact 103 and multilevel interconnects 104 are formed over a Si substrate 101. An interlayer film 106 made of a Si oxide film is formed over a fourth-level interconnect layer 105 by plasma CVD. After planarization by CMP (chemical mechanical polishing), a first sensor via 107 is formed (FIG. 4A). The first sensor via 107 connects between a predetermined interconnect of the fourth-level interconnect layer 105 and a first layer which will be described next. A WSi film having a thickness of 1 μm is formed as a first sensor layer 108 by sputtering, followed by patterning by predetermined lithography and dry etching processes, whereby a movable mass and beam of the sensor portion and an interconnect pattern for sensor are formed (FIG. 4B). An etching hole 109 is formed in the movable mass of the first sensor layer. This etching hole is formed in order to remove, for example, the interlayer film below the movable mass during etching of a sacrificial layer.

A Si oxide film 110 is then deposited by plasma CVD and it is planarized by CMP (FIG. 4C). A second sensor via (not illustrated) is formed as needed. The second sensor via connects the interconnect pattern for sensor in the first sensor layer to a second sensor layer which will be described next. A WSi film having a thickness of 1 μm is formed by sputtering as the second sensor layer and opening patterns for a minute hole 112 for cavity etching and for a stress relaxing slit are formed in the second sensor layer (FIG. 5A). The diameter of the minute hole and width of the slit are adjusted to almost 300 nm. Via the minute hole and slit opening patterns formed in the sense second layer and etching hole formed in the first sensor layer, the interlayer film (sacrificial layer) is removed by etching, whereby a cavity 114 is formed below the regions where the minute hole and slit opening patterns are present.

The opening patterns for the cavity etching minute hole and stress relaxing slit are formed while applying a so-called known hole contracting process to a conventional resist pattern formed by exposure to i ray. The WSi film is dry etched in a conventional manner with the resist pattern as a mask, but a so-called oxide film hard mask process may be employed as needed.

For etching of the interlayer film (sacrificial layer), vapor phase etching with vapor hydrofluoric acid is used in order to prevent sticking or breakage of a sealing film which will otherwise occur by a capillary force of a liquid remaining in the cavity during drying after etching. Ordinarily employed liquid phase etching with hydrofluoric acid may however be employed, depending on the gap amount.

Since the etching rate of the WSi film is very small, the movable mass and beam pattern remain in the cavity. Below the cavity region, the fourth-level interconnect layer having TiN at the uppermost layer thereof have been formed all over and the etching rate of the TiN film is very small so that the lower surface of the cavity is defined.

The interlayer films over and below the movable mass and beam pattern of the first sensor layer are removed almost simultaneously and the movable mass is suspended in the cavity by the beam pattern fixed to the side surface of the cavity. The beam undergoes elastic deformation. It deforms, absorbing the residual stress of the movable mass and beam pattern. The stress of the movable mass and beam pattern is very low so that vertical deformation of the film does not occur. The beam defined by the slits formed in the second sensor layer over the cavity also deforms, absorbing the residual stress of the second sensor layer, whereby the residual stress in the second sensor layer is reduced. Neither the breakage nor vertical deformation of the film therefore occurs.

A region in which no minute hole is located is formed in the second sensor layer at a position corresponding to an almost center position of the cavity region. At the same time, the movable mass of the first sensor layer is located to avoid the above-described region and periphery thereof. Below the region in which no minute hole is located, the sacrificial layer remains unetched so that the column of the sacrificial layer is formed in the cavity and supports the second sensor layer at the cavity center. The slits of the second sensor layer are located almost symmetrically over the cavity region so that displacement of the film due to the residual stress is very small at the cavity center. Even the fixation of the second sensor layer at the cavity center by the support has a least influence on the film stress.

The minute hole and slit opening pattern are then sealed by depositing a Si oxide film 115 on the second sensor layer by thermal CVD (FIG. 5B). A passivation film made of a Si nitride film is then formed by deposition (not illustrated) Since the width of the slit is smaller than a gap between the fourth-level interconnect layer and first sensor layer, and a gap between the first sensor layer and second sensor layer, the oxide film by thermal CVD is deposited almost uniformly on the surface of the first sensor layer and on the surface including the side walls of the minute hole and minute slit of the second layer. After the minute hole and minute slit are filled with the oxide film, it is deposited only on the surface of the second sensor layer. If necessary, an opening 116 for pad is formed on an interconnect pad formed by the fourth-level interconnect layer (FIG. 5C).

In the above description, CMP is employed for the planarization of the interlayer film on the first sensor layer. Alternatively, a step difference in the profile portion of the movable mass and beam may be relaxed by depositing a conformal Si oxide film by plasma CVD, etching the whole surface to form so-called sidewalls around the movable mass and beam and then depositing a Si oxide film. As the materials for the first sensor layer and second sensor layer, another material, for example, W (tungsten) may be employed. The irregularities on the surface of the interlayer film 110 may be reduced by adjusting the maximum slit width in the main portion of the first sensor layer pattern to sufficiently smaller than (or at least equal to) the thickness of the interlayer film 110 between the first sensor layer and second sensor layer.

As the materials for the first sensor layer and second sensor layer, a further material, for example, W (tungsten) may be employed. Materials such as W and WSi are advantageous because they can assure a sufficient etching selectivity relative to an interlayer insulating film during etching for cavity formation by hydrofluoric acid. The thickness of these films is not limited to the above-described values.

When vapor HF is used for the etching of the insulating film for the cavity formation, aluminum may be employed as the material for the first sensor layer and second sensor layer. These films may be formed by not only sputtering but also CVD. CVD sometimes causes a problem of film breakage owing to a large residual stress of the film, but it is usable in the invention because the stress is relaxed by slits.

The pattern of the uppermost-level (fourth-level) interconnect layer laid all over the lower portion of the cavity functions as an electric shield between the sensor and LSI below the uppermost-level interconnect layer. When a circuit is not placed below the sensor placement region, the shield is not always necessary and an SI substrate itself may be used as an etching stopper upon formation of the cavity. By ground connection, the second sensor layer also functions as a shield for electrically and magnetically protecting the sensor from the outside word.

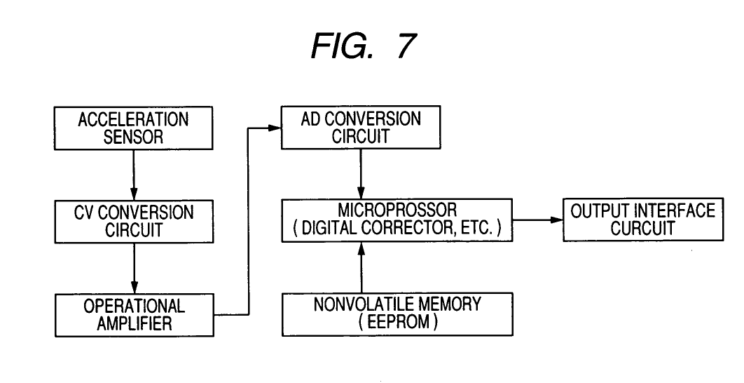

The operation of the sensor will next be described. FIG. 6 is a schematic view illustrating the planar arrangement of the first sensor layer 117 and cavity 114 of the completed sensor. In the cavity 114, the mass is fixed to the interlayer film via the beam 118 formed by the same layer. When acceleration is applied to the mass in the direction x (or y) in this drawing, the beam undergoes elastic deformation and displacement of the position of the mass in the x (or y) direction occurs in the cavity. The displacement amount is detected as a change in capacitance between a comb electrode 119 formed in a portion of the mass and a comb electrode 120 fixed to the interlayer film and protruded into the cavity. Fixed electrodes constituting a pair and having one mass-side electrode sandwiched therebetween are each electrically independent and the capacitance between one of the fixed electrode and mass and that between the other fixed electrode and mass are detected respectively (one of right and left capacitances increases and the other one decreases by the a vibration motion of a movable plate in one direction). These electrodes are electrically connected to a signal processing integrated circuit which has been integrated on the same substrate and an acceleration signal is output after signal processing such as capacitance voltage conversion. FIG. 7 is a circuit block diagram of the above-described signal detection circuit. The capacitance thus detected is digitalized, going through a capacitance voltage conversion (CV conversion) circuit, amplifier, and AD conversion circuit. After various corrections such as temperature and amplifier characteristics corrections by MCU, it is then output as acceleration.

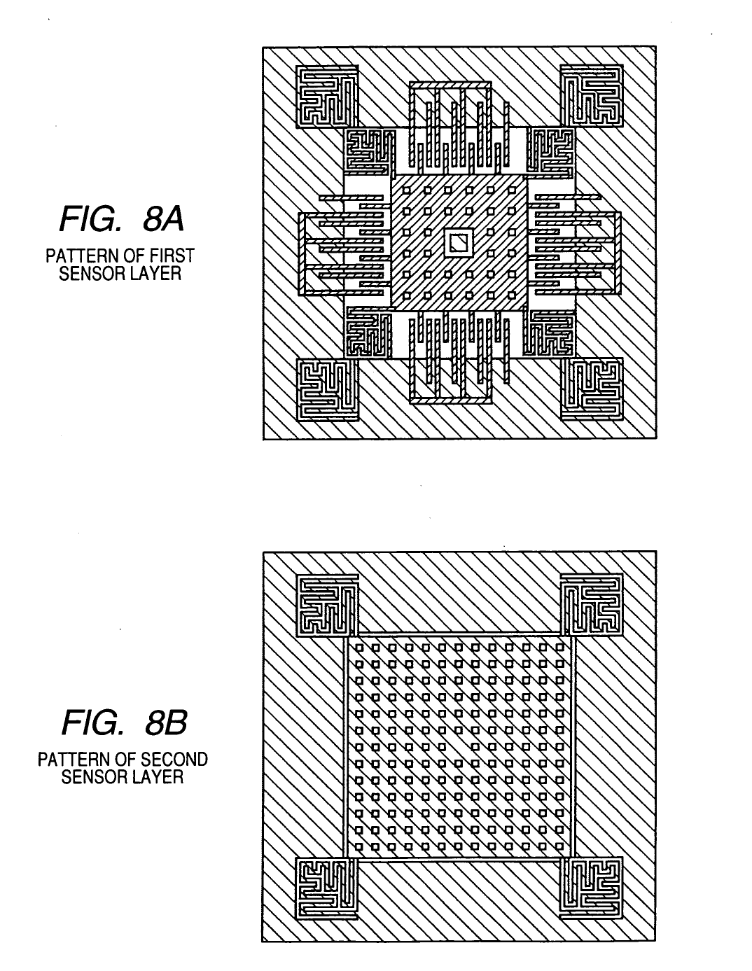

The pattern of the cavity lid formed by the second sensor layer is not limited to that illustrated in FIG. 6B but various shapes can be employed. It may be, for example, the shape as illustrated in FIG. 8B. In FIG. 8, the lid on the cavity including the mass of the acceleration sensor and beam supporting the mass is fixed to the substrate via the beam formed in the second sensor layer. When the cavity is formed, the residual stress of the lid is absorbed and relaxed by the beam deformed by the residual stress of the film. The opening around the beam is not necessarily be sealed by thermal CVD, but by depositing a thick insulating film such as Si oxide film by plasma CVD to bury it in the cavity of the opening around the beam, fixation of the beam and sealing of the cavity may be performed simultaneously while maintaining the deformed state. FIG. 8A is a schematic plan view of the first sensor layer when the lid of FIG. 8B is employed.

The beam supporting the mass is designed to be wide enough at the base portion of the cavity so that it does not easily undergo elastic deformation even by the application of acceleration to the mass. The beam is designed to be narrower at the center portion thereof than that at the base portion thereof to generate desired elastic deformation by the application of predetermined acceleration. Accordingly, the mechanical properties are determined only by the plane pattern shape and film thickness of the first sensor layer and do not depend on the dimension and shape of the cavity. The dimension and shape of the cavity are determined by the etching of the sacrificial layer and they are not so precise, but low precision of them does not have an influence on the mechanical properties of the sensor. The planar shape of the vibration body and beam is not limited to that as illustrated in the drawing. The sensor may be a monoaxial acceleration sensor in which the rigidity of the beam supporting the center mass is weakened only in one direction. Alternatively, it may be a tri-axial acceleration sensor in which the displacement in a direction perpendicular to the chip surface of the movable mass is measured by a capacitance change between the first sensor layer and the second sensor layer over the movable mass or the fourth-level interconnect below the movable mass.

### Second Embodiment

An angular rate sensor (vibration gyroscope) according to a second embodiment of the present invention will next be described. In this Embodiment, a vibration body is formed by the SOI (Silicon On Insulator) process and then sealed by the LSI wiring process.

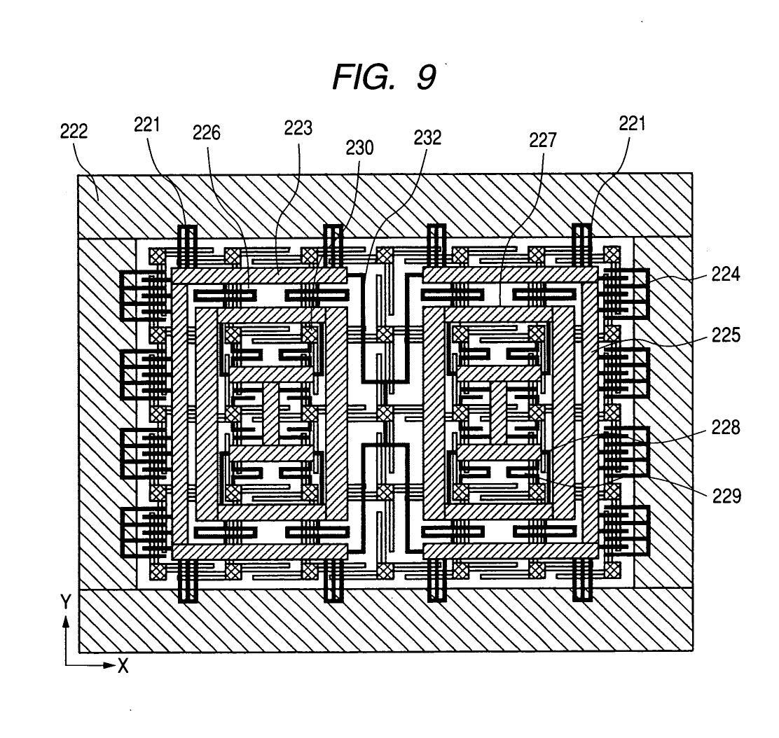

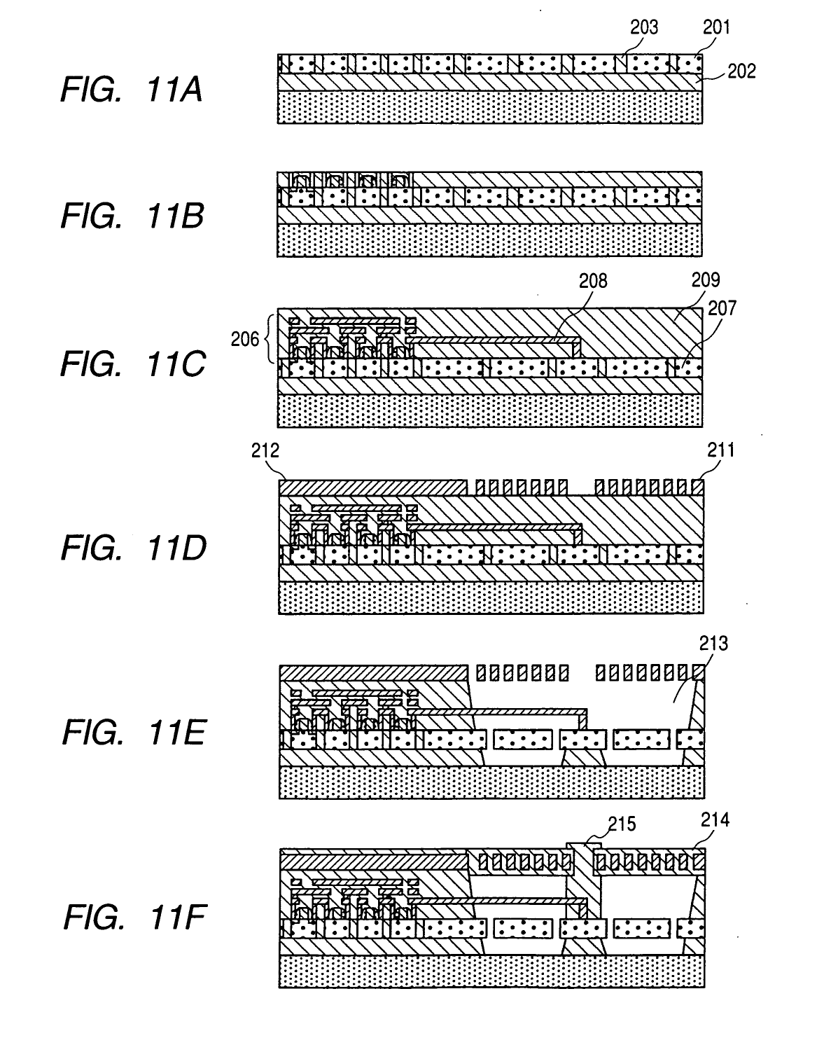

FIGS. 9, 10 and 18 are schematic views illustrating the planar configuration of a structure pattern in each layer constituting the vibration gyroscope, while FIG. 11 is a schematic view illustrating the manufacturing process of the vibration gyroscope according to this embodiment.

FIG. 9 is a plan view of the SOI layer constituting the vibration body. A layer corresponding to the first sensor layer of Embodiment 1 is also called “first sensor layer”. The first sensor layer pattern is a so-called vibration gyroscope sensor and it has a tuning-fork structure in which two vibration bodies subjected to vibration separation in an actuation (x) direction and a detection (y) direction have been coupled mechanically.

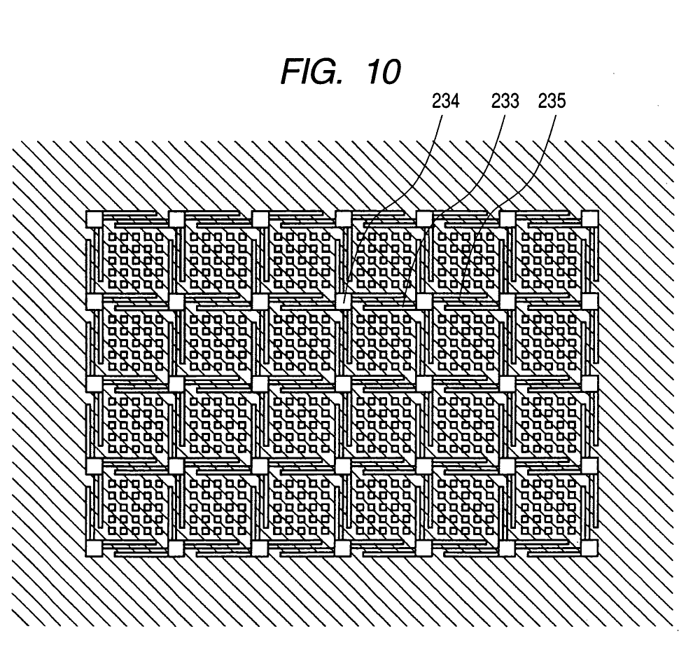

FIG. 10 is a plan view of a layer to be a lid of the cavity in which the vibration body is placed. This layer corresponding to the second sensor layer of the first embodiment is also called a second sensor layer. Cross-shaped slits 233 and 235 placed in the second sensor layer have a width minute enough to be sealed by thermal CVD as in the first embodiment, but the slits each has, at the center of the cross, a relatively large opening 234. An anchor fixed to a substrate is placed in a region surrounding the opening of the first sensor layer, while the vibration body (movable structure) is designed to be placed in a region other than the region surrounding the opening.

FIG. 11 is a schematic view illustrating the preparation process of the angular rate sensor according to the second embodiment.

For the formation of a vibration body on the SOI substrate, an opening 203 extending from the surface of the substrate to a buried insulating film 202 is formed in the SOI layer around a pattern to be a vibration body (mass and beam). The opening portion is filled with a CVD oxide film (HLD) (FIG. 11A). In accordance with the ordinary preparation process of a CMOS integrated circuit, integrated circuit transistors 204 for actuation and signal processing of the vibration gyroscope and contact 205 are formed over the SOI substrate (FIG. 11B), followed by the formation of a multilevel interconnect 206 over the integrated circuit region by the ordinary preparation process of a CMOS integrated circuit (FIG. 11C). At this time, by the contact and first-level interconnect (M1 layer) made of W, wiring connection to the anchor part at the center of the sensor is performed. Only an interlayer insulating film is deposited over the vibration body pattern and periphery thereof except the connection wiring. After the formation of the uppermost-level interconnect, an interlayer film is deposited, followed by planarization using chemical mechanical polishing (CMP) as needed, whereby minute etching holes for the formation of cavity and cavity cover film 212 having cross-shaped slits are formed (FIG. 11D). Via the minute etching holes, the interlayer film over the gyroscope, CVD oxide film filled in the opening, and buried insulating film on the SOI substrate below the vibration body (mass and beam) are removed by etching, whereby a cavity 213 is formed around the vibration body (FIG. 11E).

Simultaneously with the formation of the cavity, the beam sandwiched by two cross-shaped slits undergoes elastic deformation and absorbs and relaxes the residual stress of the second sensor layer as in the first embodiment. The etching in the depth direction stops at the substrate Si below the buried insulating film. The connection wiring made of W remains in the cavity without being etched and becomes an air wiring for electrically connecting the LSI portion to the anchor in the sensor portion.

In the final step, the minute etching holes are filled with the insulating film 214, whereby the cavity is sealed (FIG. 11F). The cavity is sealed by the following two stages. First, a first sealing film is deposited by thermal CVD under atmospheric pressure to seal therewith the minute etching holes, followed by deposition of a second sealing film by plasma CVD under low pressure to seal therewith the opening at the center of the cross-shaped slits. The second sealing film deposited on the anchor seals therewith the cavity and at the same time becomes a support 215 for fixing the second sensor layer to the substrate through the mechanical connection between the second sensor layer and anchor. Variations in the stress condition of the film, depending on the fixed position hardly occur because the second sensor layer is fixed after the internal stress thereof is relaxed by its deformation. The minute etching holes to be sealed with the first sealing film define the shape of the whole cavity. Since the cavity is sealed under low pressure, that is, the deposition condition of the second sealing film, the cavity can be sealed under nearly vacuum condition. In an application using the vibration characteristics of the structure as in this embodiment, the influence of the gas resistance around the structure is not negligible. It is therefore desired to adjust the pressure in the cavity to an almost vacuum level.

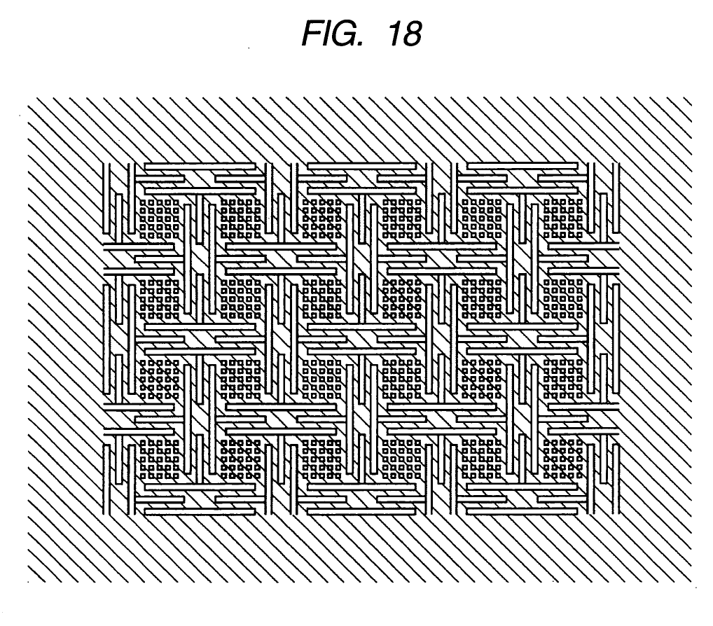

The slit patterns formed in the second sensor layer can be changed variously. FIG. 18 illustrates an example of the second sensor layer having slits different from those of FIG. 10. The width of a T-shaped slit 236 is equal to that of the slit 233 at the narrow portion thereof. In a region corresponding to the upper portion of the anchor 230 of the lid, no minute etching holes for the formation of a cavity are disposed so that no cavity is formed in the region of the anchor 230 and the interlayer film (sacrificial layer) remains and becomes a support of the lid. This makes it possible to prevent the sticking of the second sensor layer to the first sensor layer which will otherwise occur by the capillary force during the etching for the formation of the cavity. The lid is fixed at the position of each anchor and the internal stress of the lid is absorbed by the deformation of the beam formed by the slits between the anchors.

An operation principle of the angular rate sensor will next be described briefly based on FIG. 9. In the following description, the actuation axis and detection axis are considered as a coordinate system fixed to the cavity. Via a beam having the rigidity in the detection axis (y) direction much greater than the rigidity in the actuation axis (x) direction, a vibration element fixed to an interlayer film around the cavity makes a vibration a vibration motion in the actuation axis direction by an actuation electrode. The vibration element oscillates easily in the actuation axis (x) direction, but hardly moves in the detection axis direction at this time. A Coriolis element is connected to the inside of the vibration element via the beam having the rigidity in the actuation axis direction (x) much greater than the rigidity in the detection axis (y) direction. When the sensor turns around an axis perpendicular to the substrate, the Coriolis element starts elliptic motion with the aid of the Coriolis force proportional to the angular rate in the detection axis (y) direction. Inside of the Coriolis element, a detection element is connected to the Coriolis element via the beam having the rigidity in the detection axis (y) direction much greater than the rigidity in the actuation axis (x) direction. At the same time, the detection element is connected to the substrate (anchor) via the beam having the rigidity in the actuation axis (x) direction much greater than the rigidity in the detection axis (y) direction. The detection element therefore makes a vibration motion corresponding only to the component of the detection axis (y) direction of the elliptical motion of the Coriolis element. The vibration amplitude in the detection direction of the detection element is determined by measuring the amplitude of a capacitance change of the detection electrode, whereby an angular rate is determined. Two vibration bodies on the right and left sides of the drawing which are connected by mechanical coupling make oscillation in opposite phase in the actuation direction.

The actuation electrode is composed of a comb-like first actuation electrode fixed to the interlayer film around the cavity and connected to a predetermined LSI interconnect and a comb-like second actuation electrode fixed to the actuation element. An AC voltage is applied between the first and second actuation electrodes. The detection electrode is composed of a comb-like first detection electrode fixed to the anchor and connected to a predetermined LSI interconnect via the air wiring and a comb-like second detection electrode fixed to the detection element. A capacitance change between the first and second detection electrodes is synchronously detected with the vibration phase in the actuation direction of the actuation element, and thus measured. A vibration monitor or electrode for various servos may be disposed in the actuation axis direction.

In this embodiment, the mass is composed only of an SOI layer, but a contact layer, or a multilevel interconnect layer may be stacked over the SOI layer of the mass portion in order to increase the weight of the mass further. In this case, the detection electrode may be composed of a proper layer in the multilevel interconnects. Instead of the SOI layer, a thick poly Si film may be used for the formation of the movable body. In this case, this embodiment can be applied as is when a Si substrate having, successively stacked thereover, an oxide film and a poly Si film having predetermined thicknesses is employed as a substrate. Patterning of the SOI layer or thick poly Si film constituting the vibration body, that is, defining of the planar shape of the vibration body and periphery thereof by etching and filling of an oxide film (sacrificial film) in the etched portion, may be carried out either before or after the formation of the transistor of the integrated circuit portion.

The gist of this embodiment resides in sealing an inertia sensor, which has been manufactured by the known SOI technology, in a cavity having a stress-relaxed cavity lid and does not define the characteristics of the design of the inertia sensor. The planar shape or configuration is only schematically shown and can be changed as needed to obtain the optimum design.

### Third Embodiment

An application example of the present invention to an ultrasonic transducer will next be described as an application example to the formation of a diaphragm of a large area.

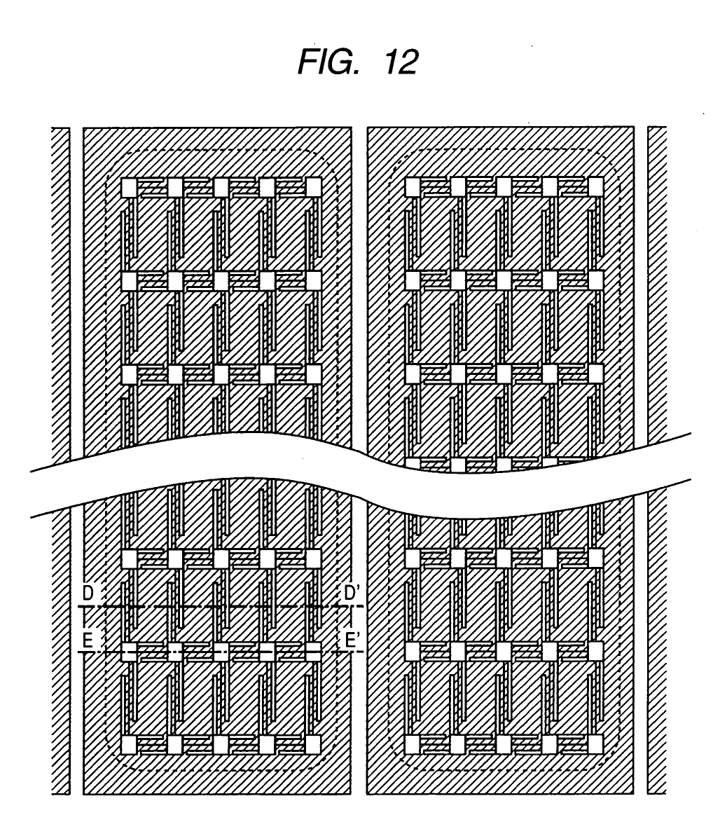

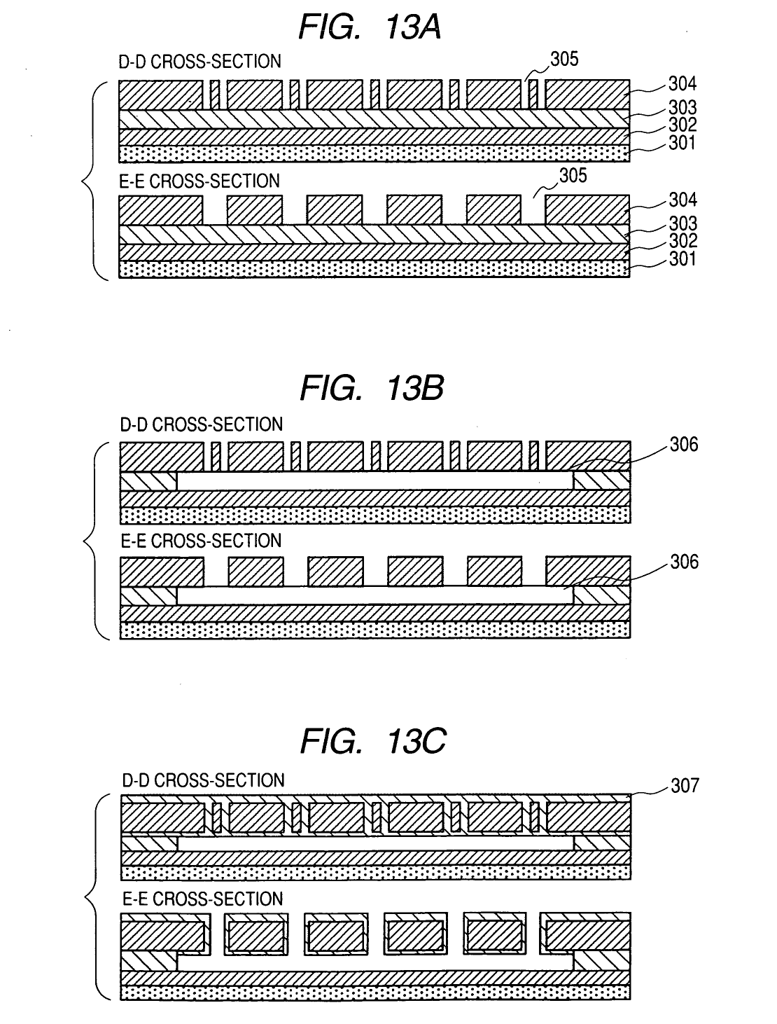

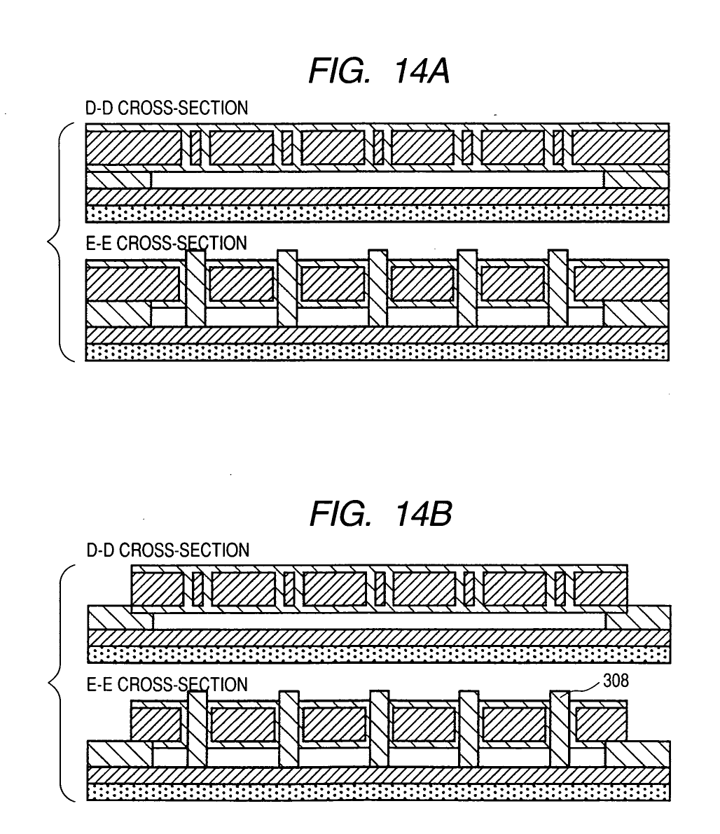

FIG. 12 is a schematic view illustrating the planar configuration of a pattern of a layer constituting a diaphragm of the ultrasonic transducer according to this embodiment, while FIGS. 13 and 14 are each a schematic view explaining the manufacturing process of the ultrasonic transducer according to this embodiment.

FIG. 12 is a plan view of a layer to be a lid of the cavity of the ultrasonic transducer (at the time of etching of a sacrificial layer). This layer corresponding to the second sensor layer of the second embodiment will hereinafter be also called second sensor layer. Different from the second sensor layer of the second embodiment, no minute etching holes are made in this embodiment. With regard to the cross-shaped slits, similar to those of the second embodiment, they have, at the narrow portion thereof, a width as minute as possible to enable sealing by thermal CVD and, at the center of the cross, a relatively large opening. A cavity is formed by the removal of an oxide film existing around the cross-shaped slit below the lid. The cavity has a width of 200 μm and has a length of 5000 μm in the longitudinal direction. It can be divided as needed in the longitudinal direction. The lid acts as one upper electrode corresponding to the cavity having a width of 200 μm and a length of 5000 μm.

FIGS. 13 and 14 are schematic views illustrating the manufacturing process of the ultrasonic transducer according to this embodiment. The cross-sectional views corresponding to the cross-sections D-D′ and E-E′ of FIG. 12 are illustrated in these FIGS. 13 and 14. The preparation process will next be described briefly. A pattern of FIG. 12 is formed by disposing a lower electrode 302 on a substrate 301, depositing an insulating film 303 and then forming an upper electrode 304. The lower electrode is a film stack of TiN, Al and TiN, the insulating film is a plasma TEOS Si oxide film, and the upper electrode is WSi made by sputtering (FIG. 13A). A portion of the insulating film (Si oxide film) is removed by etching via slits to form a cavity 306 (FIG. 13B). As in the first embodiment, a beam sandwiched by two cross-shaped slits undergoes elastic deformation simultaneously with the formation of the cavity, thereby absorbing and relaxing the residual stress of the second sensor layer. The etching in the depth direction stops at the upper surface of the lower electrode. The cavity is sealed by the following two stages. First, a first sealing film 307 is deposited by thermal CVD under almost atmospheric pressure to seal minute etching holes (FIG. 13C).

Then, a second sealing film is deposited by plasma CVD under low pressure to seal the opening at the center of the cross-shape slits (FIG. 14A). The second sealing film deposited on the anchor seals the cavity and at the same time, serves as a support which mechanically connects the second sensor layer to the anchor, thereby fixing the second sensor layer to the substrate. The second sensor layer is fixed after the internal stress of the film is released by its deformation so that the stress condition of the film hardly changes, depending on the fixed position. In such a manner, a diaphragm of a very large area can be formed stably.

In this embodiment, the slit pattern of the second sensor layer can be changed, for example, as illustrated in FIG. 18. This makes it possible to prevent the sticking of the second sensor layer to the substrate even if wet etching is employed for the formation of the cavity.

The MEMS of the present invention can be applied to various fields such as automobiles, mobile phones, amusement apparatuses, wireless apparatuses, information appliances and computers. Specific examples include physical sensors such as acceleration sensor, vibration gyroscope, and pressure sensor; RF-MEMS such as oscillator, filter and switch; and MEMS requiring sealing of its cavity (such as ultrasonic probe and Si microphone).

What is claimed is:

1. A MEMS device, having associated therewith at least one cavity, on a substrate, comprising:
a sacrificial layer formed over the substrate;
a lid comprising a thin film atop said sacrificial layer, wherein said lid at least partially covers said sacrificial layer, and wherein said lid includes at least one selected from the group consisting of a slit, a beam, and a spring, for relaxing an internal stress on said lid; and
a sealing film for filling filling a plurality of openings in said lid, wherein said sealing film at least partially seals the cavity from an opposing side of said lid.

2. The MEMS device according to claim 1, wherein:
the at least one of the beam and the spring is fixed to at least a portion of a periphery of the cavity, whereby the lid is suspended over the cavity; and at least one gap between the lid and the periphery of the cavity is filled with the sealing film.

3. The MEMS device according to claim 1, wherein:
the slits comprises:
a first slit having at least a first side and a second side longer than the first side, surrounded by a closed curve and having a predetermined width; and
a second slit substantially parallel to at least the second side of the first slit and at a predetermined distance from the first slit.

4. The MEMS device according to claim 1, wherein:
the width is greater than a maximum of an absolute value of a relative displacement of a position coordinate along a profile of the slit when subjected to displacement when the stress on said lid is relaxed during formation of the cavity.

5. The MEMS device according to claim 1, wherein:
the slits are placed in a peripheral region of the lid.

6. The MEMS device according to claim 1, wherein:
the slits are placed in a center region of the lid.

7. The MEMS device according to claim 1, wherein:
the slits are placed in a center region of the lid and the sealing film reaches a bottom portion of the cavity to thereby constitute a column for supporting the lid, and wherein the column is placed at a position not disturbing motion of a movable body of the MEMS.

8. The MEMS device according to claim 7, wherein:
the column is composed of a portion of the sacrificial layer.

9. The MEMS device according to claim 1, wherein the sealing film does not reach a bottom portion of the cavity.

10. The MEMS device according to claim 3, wherein:
a beam sandwiched between the first slit and the second slit has a width of 10 μm or less.

11. A manufacturing process for a MEMS device having at least one cavity and a movable body, comprising:
stacking a second thin film over a first thin film, wherein the first thin film is formed over a substrate,
forming a plurality of slits, and at least one beam defined by the slits, in the second thin film,
removing a portion of the first thin film via the slits to form a cavity in the first thin film below the second thin film, and
deforming at least one of the slits and the beam during said removing to form the cavity, wherein residual stress in the second thin film is relaxed by said deforming.

12. The manufacturing process of an MEMS device according to claim 11, further comprising:
forming, in addition to the plurality of slits and the beam defined by the slits, a plurality of holes in the second thin film, and
wherein said removing comprises removing a portion of the first thin film via the holes to form the cavity in the first thin film.

13. The manufacturing process of an MEMS device according to claim 11, wherein:
the first thin film is an insulating film made of one of SiO₂ and SiN, and the second thin film is one of a metal film and a semiconductor thin film selected from the group consisting of W, WSi, and poly Si.

14. The manufacturing process of an MEMS device according to claim 11, further comprising:
sealing the holes and the slits by a sealing film.

15. A manufacturing process of an MEMS device, further comprising:
leaving the first thin film in a portion of the cavity to allow the first film to serve as a support for the second thin film.
